(19) United States
(12) Patent Application Publication
(10) Pub. No.: US 2025/0079261 A1
(43) Pub. Date: Mar. 6, 2025

(54) SEMICONDUCTOR PACKAGES WITH THERMAL DISSIPATION

(71) Applicant: UTAC Headquarters Pte. Ltd., Singapore (SG)

(72) Inventors: IL Kwon SHIM, SINGAPORE (SG); Roel Adeva ROBLES, SINGARORE (SG)

(21) Appl. No.: 18/818,632

(22) Filed: Aug. 29, 2024

Related U.S. Application Data
(60) Provisional application No. 63/579,297, filed on Aug. 29, 2023.

(51) Int. Cl. H01L 23/433; H01L 21/48; H01L 21/56; H01L 23/00; H01L 23/31; H01L 23/495; H01L 23/498; H01L 25/065

(52) U.S. Cl. CPC H01L 23/4334; H01L 21/4882; H01L 21/563; H01L 21/565; H01L 23/3135; H01L 23/49568; H01L 23/49838; H01L 25/0657; H01L 24/16; H01L 24/32; H01L 24/40; H01L 24/48; H01L 24/73; H01L 24/96; H01L 24/97; H01L 2224/16227; H01L 2224/32145; H01L 2224/32245; H01L 2224/40095; H01L 2224/40247; H01L 2224/48247; H01L 2224/73221; H01L 2224/73263; H01L 2224/73265; H01L 2224/95001; H01L 2224/96; H01L 2224/97; H01L 2225/0651; H01L 2225/06524; H01L 2225/06589; H01L 2924/351

(57) ABSTRACT

The present disclosure is directed to improving heat dissipation to provide more reliable semiconductor packages. The semiconductor package may be, for example, a lead frame including one or multiple dies attached thereto. The semiconductor package may include only wire bonds or a combination of clip bonds and wire bonds. The package includes at least primary and secondary heat dissipators to improve heat dissipation. In some embodiments, the package includes a tertiary heat dissipator to further improve heat dissipation.

### CROSS-REFERENCE TO RELATED APPLICATION

This application claims the benefit of U.S. Provisional Application Ser. No. 63/579,297 filed on Aug. 29, 2023, which is herein incorporated by reference in its entirety for all purposes.

### FIELD OF THE INVENTION

The present invention generally relates to semiconductor packages and the manufacturing method of such packages. More specifically, the present invention is directed to improve heat dissipation within the package to provide more reliable semiconductor packages.

### BACKGROUND

As integrated circuits (ICs) or semiconductor chips become more and more dense, a greater and greater amount of heat is generated in their operation. Excessive heat can cause reliability issues in the ICs.

Therefore, from the foregoing discussion, there is a desire to provide effective and efficient heat dissipation in ICs.

### SUMMARY

Embodiments relate to semiconductor devices and methods of forming semiconductor devices with efficient heat dissipation. In one embodiment, a method for forming a semiconductor package includes providing a package substrate, the package substrate having top and bottom package substrate surfaces. The top surface is configured with a die attach pad (DAP) and package pads. The method also includes attaching a bottom die surface of a die to the DAP. The die is electrically coupled to the package pads. The method also includes attaching a primary heat dissipator to the package substrate and a top die surface of the die. The primary heat dissipator includes a planar member disposed over the top die surface and is configured to dissipate heat from the die. The method also includes encapsulating the package substrate with an encapsulant. The encapsulant covers the package substrate and encases the die and the primary heat dissipator. A top encapsulant surface is coplanar with a top planar member surface. The method further includes forming a secondary heat dissipator on the top encapsulant surface. The secondary heat dissipator contacts the top planar member surface of the primary heat dissipator to enhance heat dissipation from the die.

In another embodiment, a semiconductor package is disclosed. The semiconductor package includes a package substrate, the package substrate having top and bottom package substrate surfaces. The top surface is configured with a die attach pad (DAP) and package pads. The semiconductor package also includes a die having top bottom die surfaces. The bottom die surface is disposed on the DAP and the die is electrically coupled to the package pads. The semiconductor package also includes a primary heat dissipator attached to the package substrate and a top die surface of the die. The primary heat dissipator includes a planar member disposed over the top die surface and is configured to dissipate heat from the die. The semiconductor package also includes an encapsulant. The encapsulant covers the package substrate and encases the die and the primary heat dissipator. A top encapsulant surface is coplanar with a top planar member surface. The semiconductor package further includes a secondary heat dissipator disposed on the top encapsulant surface. The secondary heat dissipator contacts the top planar member surface of the primary heat dissipator to enhance heat dissipation from the die.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, with emphasis instead generally being placed upon illustrating the principles of the invention. In the following description, various embodiments of the present invention are described with reference to the following drawings, in which:

FIGS. 1a-1e show simplified cross-sectional views embodiments of a wire-bonded semiconductor package with thermal dissipation;

FIGS. 1f-1g shows a simplified cross-sectional view of embodiments of a flip-chip semiconductor package with thermal dissipation;

FIG. 1h shows a simplified cross-sectional view of an embodiment of a stacked chip semiconductor package with thermal dissipation;

FIGS. 2a-2e show various simplified views of a process for forming a semiconductor package with thermal dissipation, with subscript 1 corresponding to a top view, subscript 2 corresponding to a cross-sectional view along A-A and subscript 3 corresponding to a cross-sectional view along B-B. FIG. 2b shows simplified 3D and side views of another embodiment of a semiconductor package with a shielding structure; and

FIG. 3 shows a simplified cross-sectional view of another embodiment for forming a semiconductor package with thermal dissipation.

### DETAILED DESCRIPTION

Embodiments relate to semiconductor packages and the manufacturing method of such packages. More specifically, the present invention is directed to improving thermal dissipation in the packages.

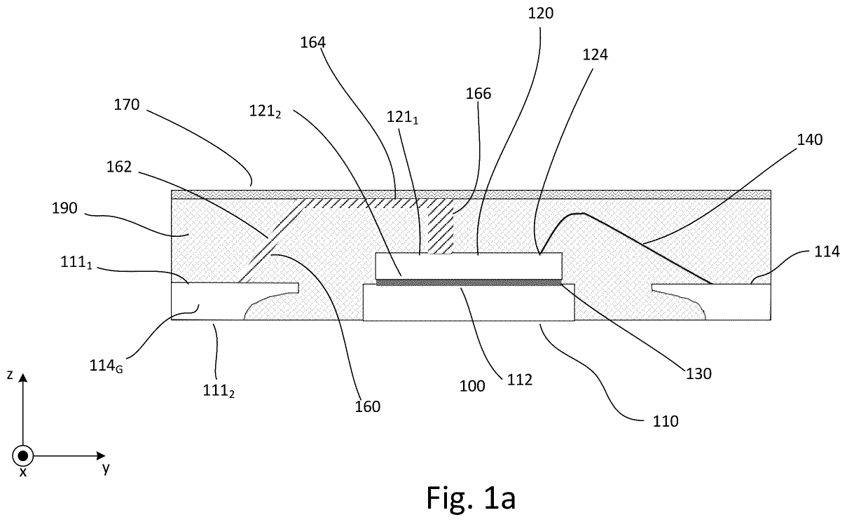

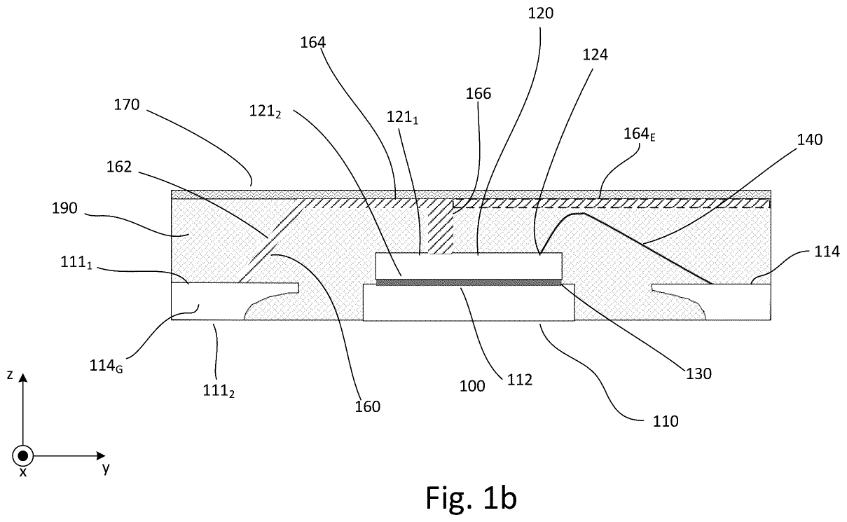

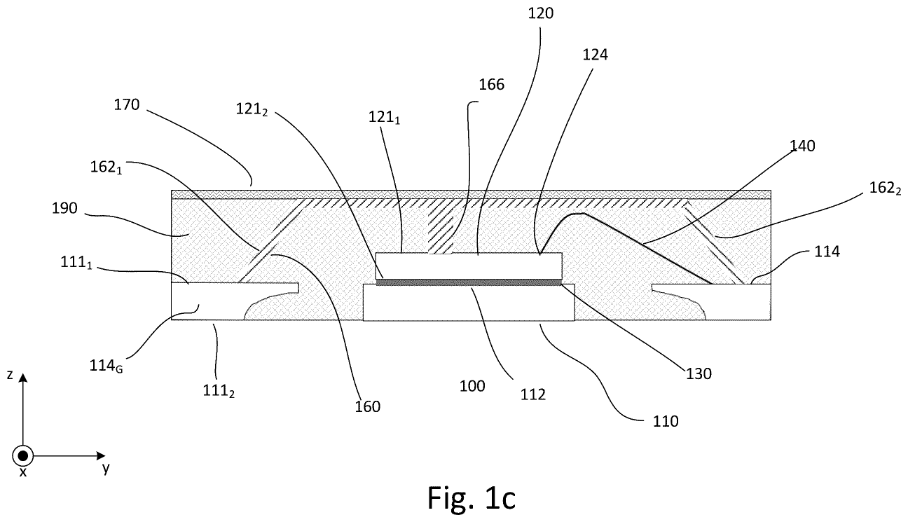

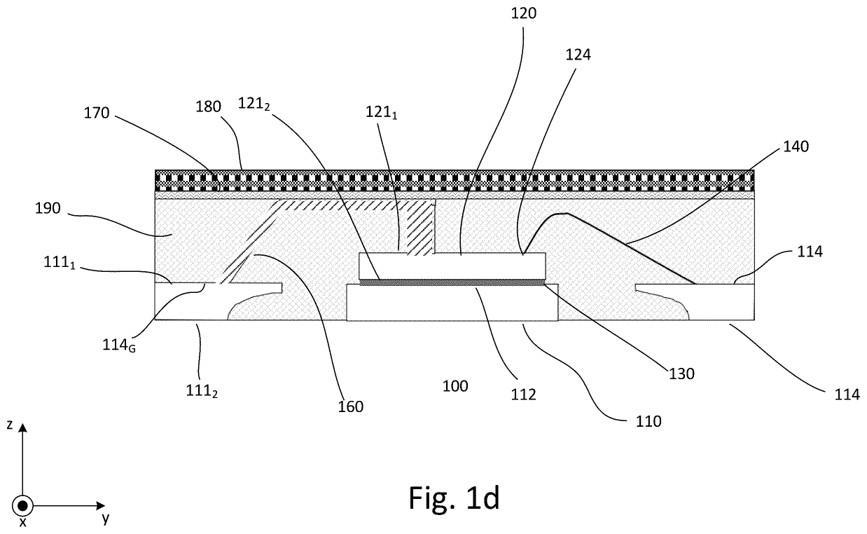

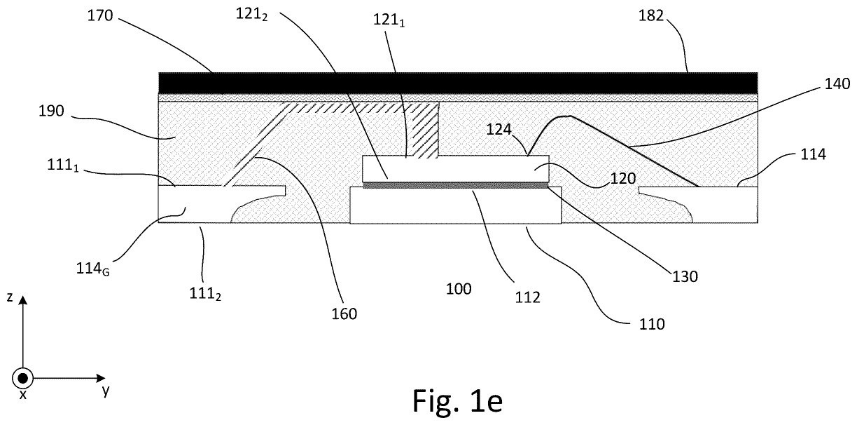

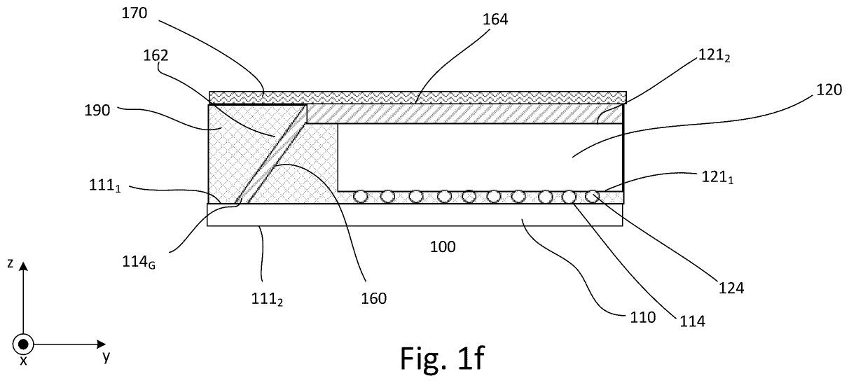

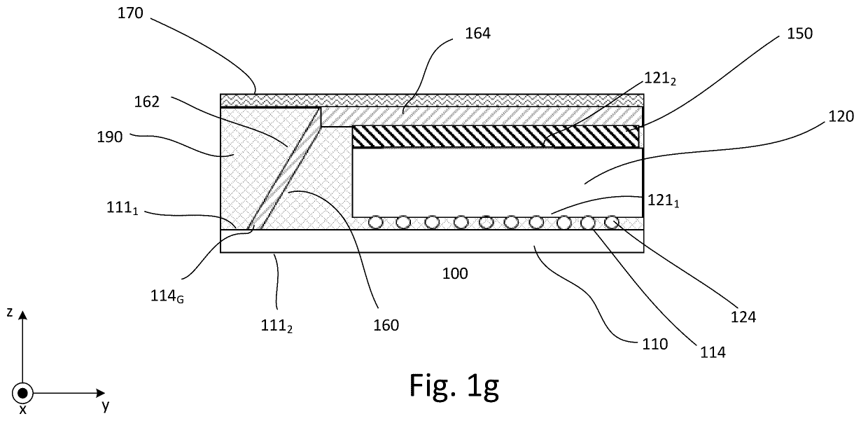

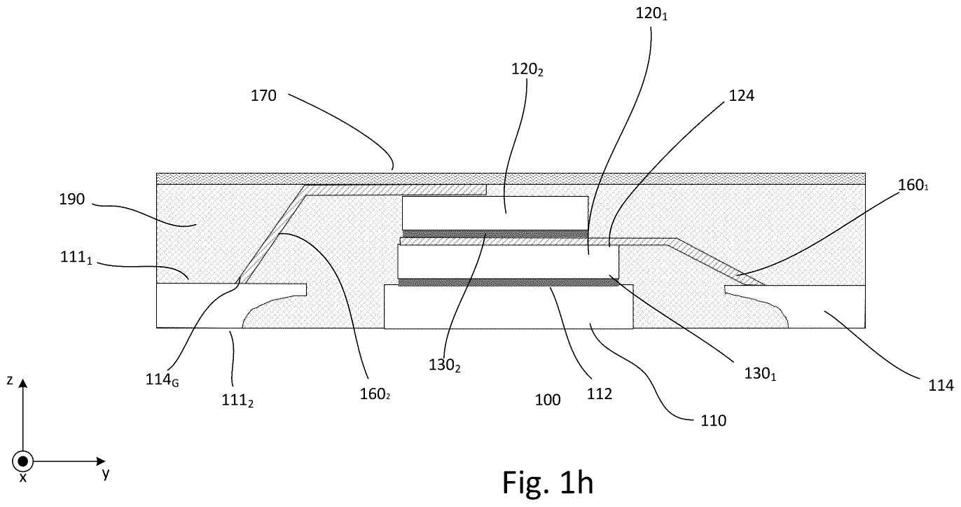

FIGS. 1a-1e show simplified cross-sectional views of various embodiments of a semiconductor package 100. Referring to FIG. 1a, the semiconductor package 100, for example, is a package for an integrated circuit (IC). The IC, for example, may be a power IC, such as a power metal oxide semiconductor field effect transistor (MOSFET). Providing a semiconductor package for other types of ICs may also be useful.

As shown, the semiconductor package includes a package substrate 110 having opposing first and second major surfaces 1111 and 1112. The first major surface may be referred to as the top package substrate surface and the second major surface may be referred to as the bottom package substrate surface. Other designations for the package substrate surfaces may also be useful.

The package substrate, in one embodiment, is a lead frame, such as a copper (Cu) or copper alloy lead frame. Other types of conductive materials, such as aluminum (Al), nickel (Ni), silver (Ag), gold (Au), alloys thereof, or a combination thereof may also be used to form the lead frame. Providing other types of package substrates, including laminate package substrates, ceramic substrates and mold-based substrates, for the semiconductor package may also be useful.

The package substrate may be a package substrate strip having a plurality of package substrates. For example, the package substrate may be a lead frame strip with a row or matrix of lead frames or package substrate units. This enables processing of multiple packages in parallel before they are subsequently singulated into individual packages.

The package substrate, as shown, is configured with a die-attach pad (DAP) 112 and package pads 114 or fingers. The package pads provide connections to die pads of a die of the package. For example, package pads 114 on the top substrate surface are connected to the die pads. Package contacts (not shown) are disposed on the bottom package substrate surface of the package pads. The package contacts serve as package terminals, enabling external connections to the die via the package contacts. The number of package pads may depend on the configuration of the die and/or the package. The package pads may be disposed on one or more sides of the DAP. As shown, the package pads are disposed on the opposing sides of the DAP along the y-direction. Other configurations of the package pads may also be useful. It is also understood that not all package pads are active package pads for connecting the die pads of the die. A package substrate may be designed to accommodate more than one type of die, providing design flexibility. In addition, the package substrate may be configured for other types of dies, such as flip chips.

The DAP is configured to accommodate a die. For example, a die 120 is attached to the surface of the DAP. The die includes first and second opposing major surfaces 121₁ and 121₂. Die pads 124 are disposed on the first surface (active die surface). The die pads serve as die terminals. For example, the die pads provide external connections to the internal circuitry of the die. In one embodiment, the second surface (inactive surface) of the die is attached to the DAP. An adhesive 130 may be used to attach the die to the DAP. The adhesive may be an adhesive tape or a thermal or UV curable adhesive. Other types of adhesives may also be used. In some cases, where the DAP serves as a terminal or terminals, a conductive adhesive may be employed to connect the DAP to a die pad on the bottom surface of the die (bottom die surface attached to the DAP).

In one embodiment, wire bonds 140 connect die pads 124 of the die to package pads 114. For example, wire bonds 140 connect die pads on the top die surface of the die to package pads on the top package substrate surface.

The semiconductor package includes a primary heat dissipator 160. The primary heat dissipator, in one embodiment, is in contact with the top die surface and the package substrate. By directly contacting the die, the primary heat dissipator provides a heat path for the die to dissipate heat thereto. In one embodiment, the primary heat dissipator is coupled to a ground. For example, the primary heat dissipator is coupled to a ground pad 114_{G} of the package substrate. Connecting the primary heat dissipator to ground provides an electrical connection with the package substrate.

In one embodiment, the primary heat dissipator is a heat dissipator structure. For example, the primary heat dissipator is pre-formed from a thermally conductive sheet (heat dissipator sheet), such as copper or copper-alloy. Other types of thermally conductive materials may also be useful. Pre-forming may be achieved by, for example, stamping. Other techniques for pre-forming the primary thermal structure may also be useful.

In one embodiment, pre-forming the primary heat dissipator includes pre-forming a plurality of primary heat dissipators on the heat dissipator sheet. The number and arrangement of heat dissipators should preferably match the number of package substrates of the package substrate strip. The heat dissipator sheet may be attached to a package substrate strip with a plurality of package substrates to form a plurality of packages in parallel. After the packages are completed on the package strip, it is singulated, separating the package strip into individual packages.

The primary heat dissipator is configured to be disposed over the package substrate. For example, the primary heat dissipator is configured to cover at least a portion of the die. As shown, the primary heat dissipator includes a leg member 162, a planar member 164 and a die connector member 166. The leg member and die connector member extend downward from first and second opposing ends of the planar member. The leg member extends to the top package substrate surface while the die connector member extends to and contacts the top surface of the die. The leg member may be coupled to ground via the ground package pad 114_{G}. The primary heat dissipator may be attached to the package substrate and die surface using an adhesive, such as a thermal or UV curable adhesive or adhesive tape. Other techniques for attaching the heat dissipator to the package substrate and die may also be useful.

The leg member, as shown, extends downward from the planar member at an angle greater than 90°. For example, the angle between the leg member and planar member is slightly greater than 90°. Providing a leg member extending from the planar member at about 90° may also be useful. As for the die connector member, it extends downward from the planar member at about 90°. A foot member (not shown) may be provided for the leg and/or die connector members. The foot member may extend horizontally from the end of the leg and/or die connector member to provide a greater surface area for attaching to the package substrate and/or the die top surface. The leg member is configured to elevate the planar member over the top die surface. In one embodiment, the planar member is elevated above the wire bonds. For example, the planar member should be at least about more than +/−75 microns above the wire bonds. Providing a leg member which elevates the planar member over the die by other heights or distances above the wire bonds may also be useful. Other configurations of the leg, planar and die connector members may also be useful.

The primary heat dissipator may extend a complete width (sides opposite the leg die connector members) of the package. For example, a portion of the planar member may serve as the die connector member while another portion (not shown) continues to the edge of the package. Other configurations or shapes of the primary heat dissipator may also be useful. For example, the primary heat dissipator can have any shape so long as it is connected to the die and to the package substrate. In one embodiment, the primary heat dissipator can have any shape so long as it is connected to the die and to a ground pad of the package substrate. The larger or greater the surface area of the primary heat dissipator, the more heat it can dissipate from the die.

An encapsulant 190 encapsulates the die and package substrate. The encapsulant, for example, is a mold compound, such as an epoxy molding compound. Other types of encapsulants may also be useful. In one embodiment, the encapsulant covers the die, wire bonds and at least sides of the shield structure. As shown, the sides of the encapsulant are aligned with the edges of the package substrate. In other embodiments, the encapsulant may extend slightly beyond the sides of the lead frame. In one embodiment, a top surface of the encapsulant may be coplanar with the top of the planar member of the primary heat dissipator. For example, the top surface of the planar member of the primary heat dissipator is exposed by the encapsulant. The encapsulant also fills the gaps in the package substrate, leaving the bottom of the package pads exposed. Other configurations of the encapsulant may also be useful.

In one embodiment, the encapsulant may be a molded encapsulant. For example, an epoxy mold compound is injected using, for example, injection or transferring molding. In such cases, the mold compound covers the top of the planar member. Back grinding is performed to expose the planar member of the primary heat dissipator. This produces a grounded top encapsulant surface as well as a grounded top planar member surface. Alternatively, the mold compound is deposited to be coplanar with the planar member, exposing the planar member surface. For example, film-assisted molding may be employed. This produces an un-grounded top encapsulant surface as well as an-grounded top planar member surface. Other techniques may also be useful to encapsulate the die.

In some embodiments, the package includes a secondary heat dissipator 170 disposed on the top encapsulant surface. The secondary heat dissipator contacts the top surface of the planar member of the primary heat structure. For example, the primary and secondary heat dissipators are thermally connected to each other. Providing the secondary heat dissipator increases heat dissipation performance of the primary heat dissipator. In one embodiment, the secondary heat dissipator covers the entire top surface of the encapsulant.

The secondary heat dissipator, in one embodiment, is a metallic layer. The metallic layer is a thermally conductive metallic layer, such as copper or copper alloy. In one embodiment, the metallic layer is a thin film metallic layer. The thin film metallic layer may be a sputtered metallic layer. For example, the thin film metallic layer may be deposited on the encapsulant by sputtering. In other embodiments, the metallic layer may be a plated metallic layer. For example, the metallic layer may be formed by plating, such as electro or electroless plating. In the case of a plated metallic layer, it is only formed on the exposed planar member of the primary heat dissipator. For the cases of thin film and plated metallic layers, they are relatively thin, such as about 1-3 μm thick. Other thicknesses may also be useful. For example, thicker metallic layers may be a spray coated metallic layer or glued metallic sheet, such as with printed glue or paste.

FIG. 1b shows another embodiment of a package 100. The package is similar to the package of FIG. 1a. For example, the package is the same as the package of FIG. 1a except for the primary heat dissipator 160. Common elements may not be described or described in detail. As shown, the planar member 164 of the primary heat dissipator 160 extends from the length of the package from the leg member 162. This increases the surface area of the primary heat dissipator of FIG. 1a, enhancing its heat dissipation.

FIG. 1c shows another embodiment of a package 100. The package is similar to the package of FIGS. 1a-1b. For example, the package is the same as the package of FIGS. 1a-1b except for the primary heat dissipator 160. Common elements may not be described or described in detail. As shown, the primary heat dissipator includes first and second leg members 162₁₋₂ which extend downward from opposing first and second ends of the planar member 164 and connect to the package substrate. The second leg may be connected to a ground pad of the package substrate. Alternatively, it may be connected to an inactive package pad or not to any package pads at all. Between the leg members, the die connector 166 extends downward from the planar member to contact the top die surface 1211. This configuration provides an increased surface area of the primary heat dissipator over that of FIG. 1a, enhancing its heat dissipation.

FIG. 1d shows another embodiment of a package 100. The package is similar to the package of FIG. 1a. For example, the package is the same as the package of FIG. 1a except that it includes a tertiary heat dissipator 180 disposed over the secondary heat dissipator 170. In addition, the secondary heat dissipator can be configured as FIG. 1b or 1c. Other configurations of the secondary heat dissipator may also be useful. Common elements may not be described or described in detail.

In one embodiment, the tertiary heat dissipator includes a thick tertiary heat dissipator. For example, the thick tertiary heat dissipator is a thick metallic layer. The thick metallic layer, for example, may be a copper or copper-alloy metallic layer. Other types of thermally conductive metallic layers may also be used. The thick tertiary heat dissipator may be about 20 μm thick or greater. For example, the thick tertiary heat dissipator, such as the thick metallic layer, is at least about 20 μm in thickness. Other thicknesses may also be useful. The thicker the layer, the more heat it can dissipate.

In one embodiment, the thick metallic layer is a spray-coated metallic layer or an attached metallic layer. An attached metallic layer, for example, may be a glued metallic layer. The glue may be a dispensed or a printed adhesive which is subsequently cured by heating. Alternatively, the glue may be a printed paste which is subsequently sintered. Other techniques or processes for disposing the thick metallic layer over the secondary heat dissipator may also be useful. The tertiary heat dissipator enhances heat dissipation over the packages of FIGS. 1a-1c.

FIG. 1e shows yet another embodiment of a package 100. The package is similar to the package of FIG. 1d. For example, the package is the same as the package in FIG. 1d except that the tertiary heat dissipator 180 includes a heat sink disposed over the secondary heat dissipator 170. In addition, the secondary heat dissipator can be configured as FIG. 1b or 1c. Other configurations of the secondary heat dissipator may also be useful. Common elements may not be described or described in detail.

In one embodiment, the heat sink is attached to the secondary heat dissipator. For example, the heat sink is a pre-formed heat sink which is attached to the secondary heat dissipator. Attaching the heat sink, for example, may be achieved using a thermal conductive adhesive. The heat sink, for example, may be a metallic structure heat sink configured with fins to increase surface area to improve heat dissipation. The material of the heat sink may be a copper-based material or a copper plated structure with other materials, such as, zinc oxide or nickel. Other types of heat sinks may also be useful.

FIG. 1f shows another embodiment of a package 100. The package includes similar components as the packages of FIGS. 1a-1e. Common elements may not be described or described in detail.

FIG. 1f shows another embodiment of a package 100. The package includes similar components as the packages of FIGS. 1a-1e. Common elements may not be described or described in detail.

In one embodiment, the semiconductor package includes a package substrate 110 having opposing first or top and second or bottom major surfaces 1111 and 1112. The package substrate, in one embodiment, is configured for a flip-chip type of die 120. A flip-chip includes die bump contacts 124 on its active surface 1211. The package substrate includes package pads 114 on the top package substrate surface 1111. The active surface of the flip-chip faces the die package. The die contacts are coupled to package pads on the top package surface. The opposing inactive die surface 1212 is facing away from the package substrate.

The package substrate may be a package substrate strip having a plurality of package substrates. For example, the package substrate may be a lead frame strip with a row or matrix of lead frames or package substrate units. This enables the processing of multiple packages in parallel before they are subsequently singulated into individual packages.

In one embodiment, a primary heat dissipator 160 is a step-shaped structure having a planar member 164 and a leg member 162 extending from a first side of the leg member downward to contact the package substrate surface. Since the die is a flip-chip, in one embodiment, the planar member is configured to directly contact the inactive die surface. For example, the primary heat dissipator does not have a die connector member extending downward to contact the die surface. This is because the die surface is the inactive die surface. In one embodiment, the primary heat dissipator leg member is connected to a ground package pad 114G. The primary heat dissipator may extend the width of the die package. The planar member may extend the length of the package from the leg member to the opposing edge of the die package.

An encapsulant 190 encapsulates the die, package substrate and primary heat dissipator. In one embodiment, a top surface of the encapsulant is coplanar with the top of the planar member of the primary heat dissipator. For example, the top surface of the planar member of the primary heat dissipator is exposed through the encapsulant.

In one embodiment, the package includes a secondary heat dissipator 170 disposed on the top encapsulant surface, contacting the planar member of the primary heat dissipator. In some embodiments, a tertiary heat dissipator (not shown) may be disposed on the secondary heat dissipator, as described in FIGS. 1d-1e.

Also as shown, an edge of the die opposing the side having the leg member is aligned with the edge of the package. In other embodiments, the package substrate may extend beyond the edge of the die. In such cases, an encapsulant would encase the edge of the die opposing the leg member. In such cases, the planar member may be configured to extend the length of the die, as shown in FIG. 1b or to include another leg member, as shown in FIG. 1c. Other configurations of the primary heat dissipator may also be useful.

FIG. 1g shows yet another embodiment of a package 100. The package is similar to what is described in FIG. 1f. Common elements may not be described or described in detail. As shown, the flip-chip 120 includes a die heat dissipator 150 on the inactive die surface 121₂. The die heat dissipator, for example, is a heat slug attached to the inactive die surface. As shown, the heat slug has the same surface area as the inactive die surface. The heat slug is formed of a heat conductive material, such as copper or copper alloy. In one embodiment, the heat slug is a metallic layer attached to the inactive die surface. The metallic layer, for example, is attached using an adhesive. In one embodiment, a metallic layer is attached to an inactive surface of the wafer and subsequently singulated into individual flip-chips. The primary heat dissipator contacts the die heat dissipator. In one embodiment, a tertiary heat dissipator (not shown) may be disposed over the secondary heat dissipator.

FIG. 1h shows another embodiment of a package 100. The package may be similar to those described in FIGS. 1a-1g. Common elements may not be described or described in detail.

As shown, the package is a stacked multi-chip package in which a second die 120₂ is stacked on top of a first die 120₁. In one embodiment, a first primary heat dissipator 160₁ is disposed over the top of the first die and a second primary heat dissipator 160₂ is disposed on the top surface of the second die. The top surfaces of the dies, as shown are active surfaces. The primary heat dissipators include a planar member and a leg member extending from one side of the planar member to contact the package substrate surface, creating a step-like profile with slanted leg members. Other configurations of the leg members may also be useful.

In one embodiment, the primary leg members are patterned or pre-formed to serve as clip bonds connecting a die to package pads, including a ground pad, As shown, the leg members of the first and second primary heat dissipators extend to the package substrate on different sides, such as opposing sides. This avoids contacting or interfering with each other. For example, a primary heat dissipator is configured to contact die pads and package pads, including a ground pad to connect the primary heat dissipator to ground without shorting other die pads.

A secondary heat dissipator is 170 disposed on the top encapsulant surface, which exposes the planar member surface of the second primary heat dissipator. In some embodiments, a tertiary heat dissipator (not shown) is disposed on the secondary heat dissipator.

As described, the primary heat dissipators serve as both clip bonds for electrically connecting the dies to package pads as well as heat dissipation. Also as shown, more than two dies can be stacked together to form a multi-stacked die. Other configurations of the stacked die package may also be useful. In addition, the package may be a multi-die package with unstacked dies or a combination of stacked and unstacked dies.

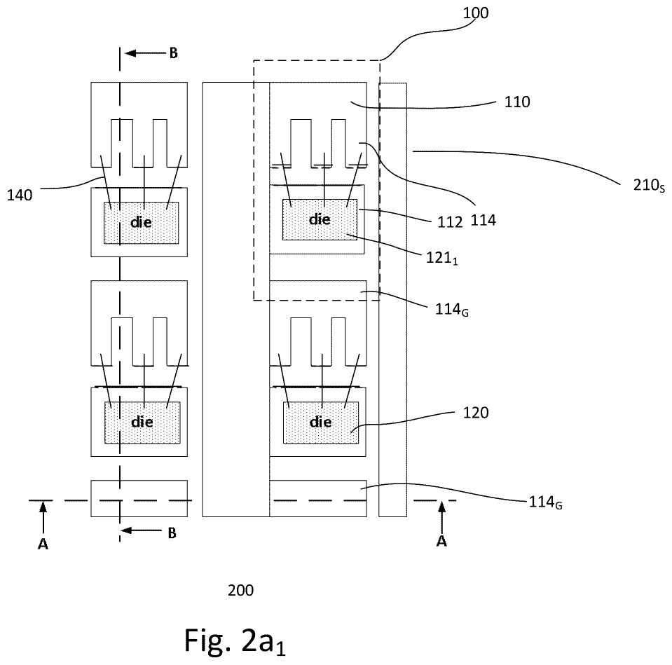

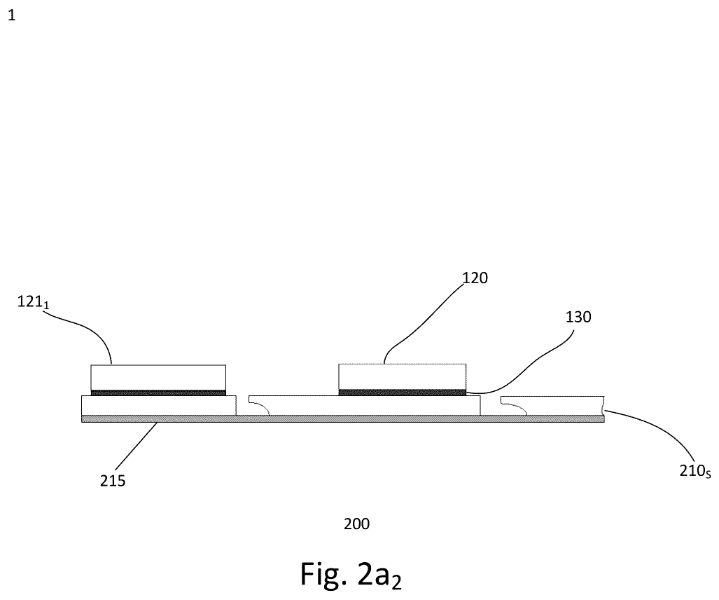

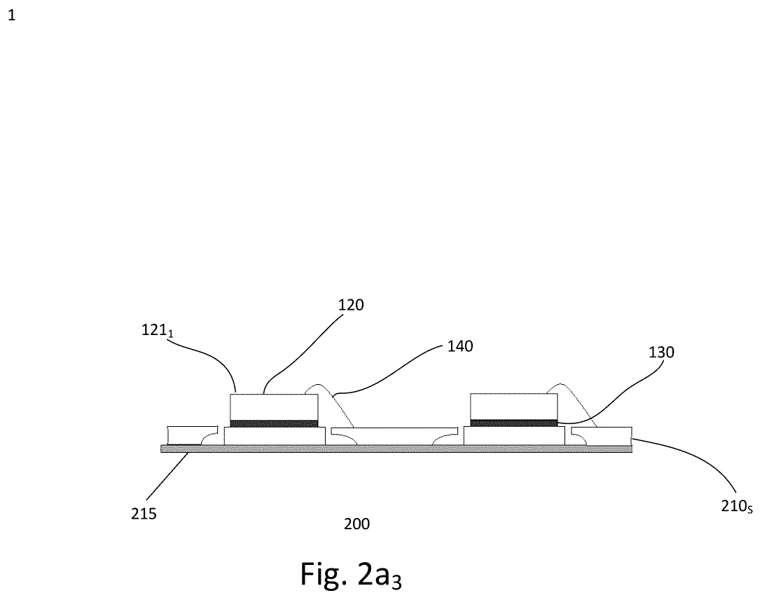

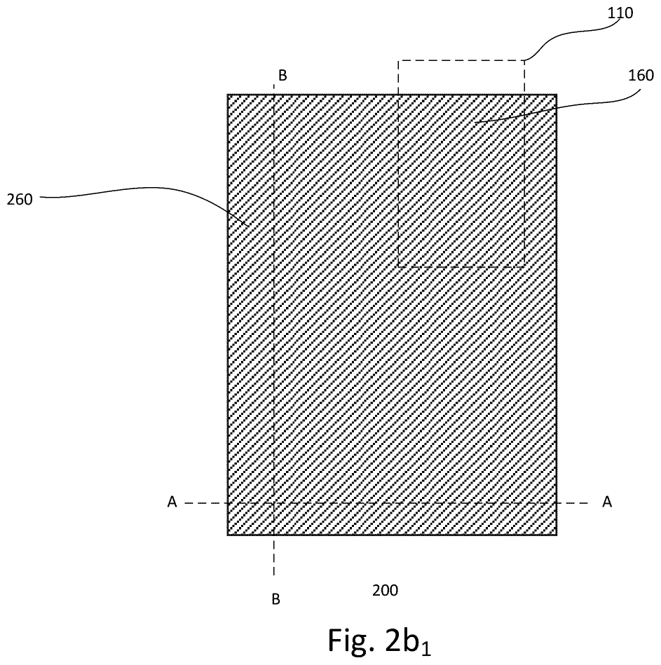

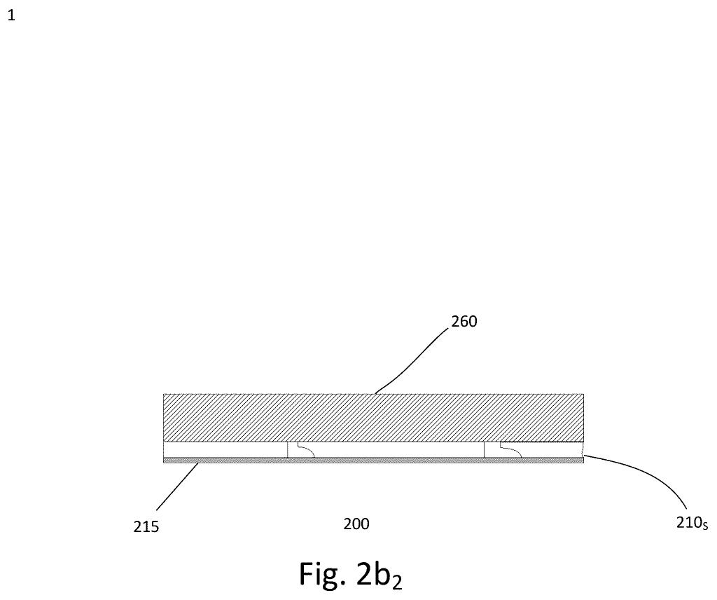

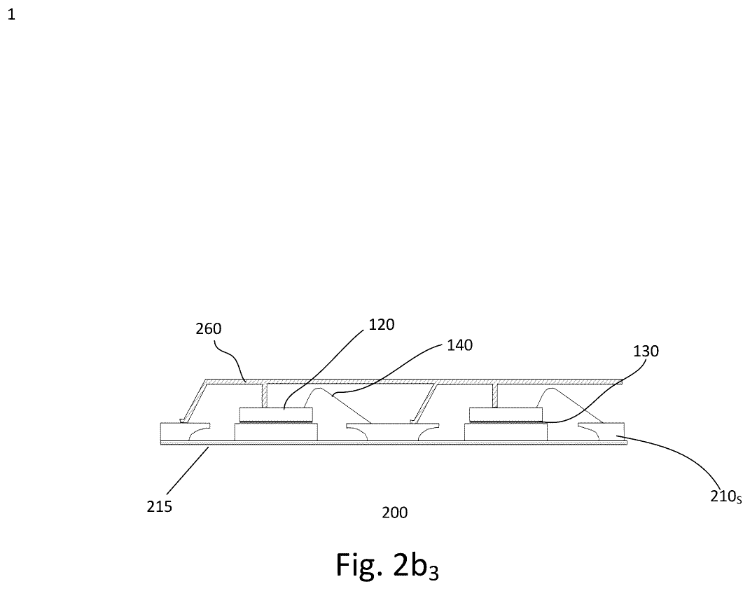

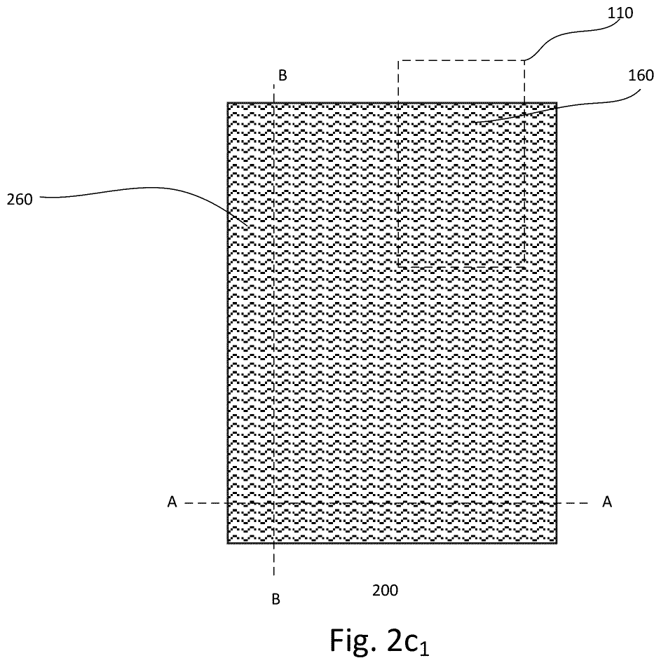

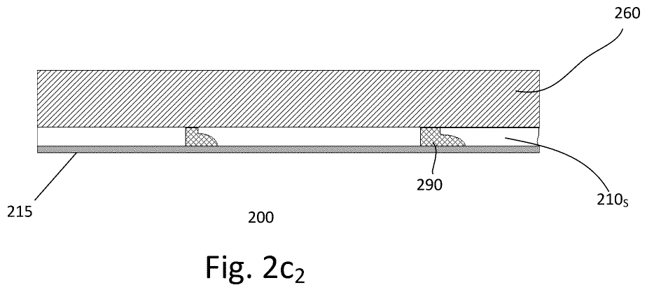

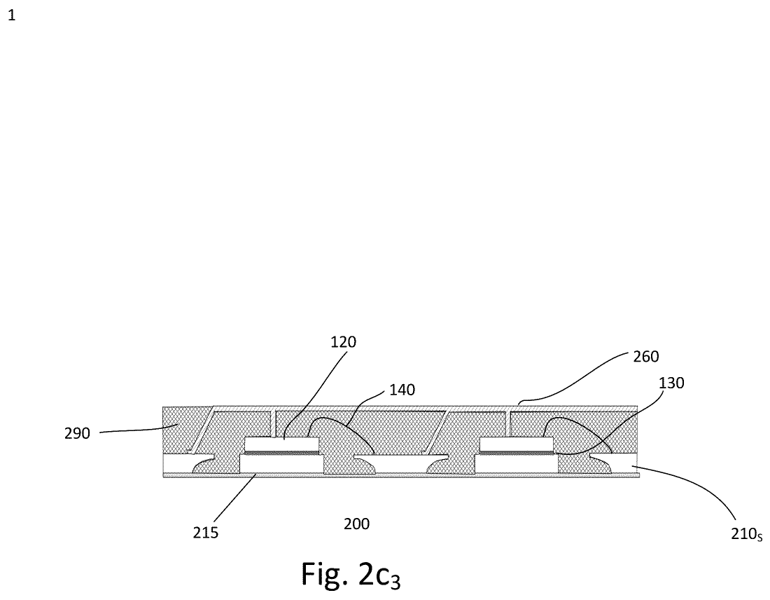

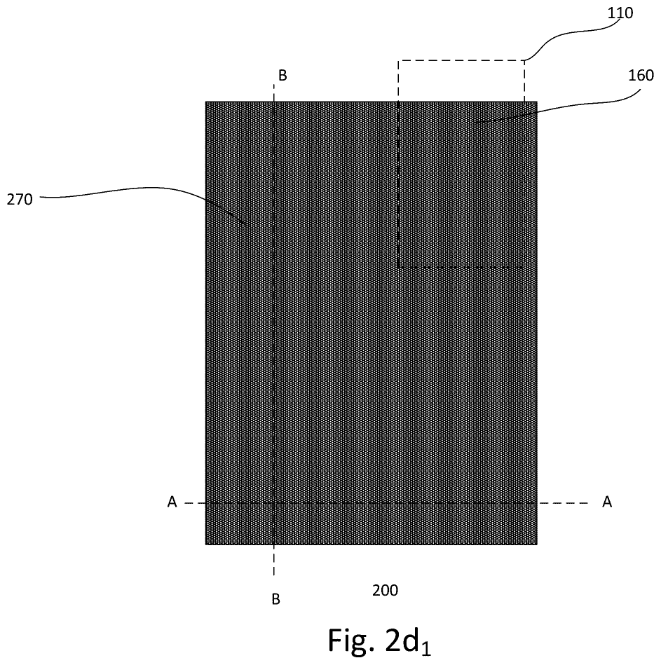

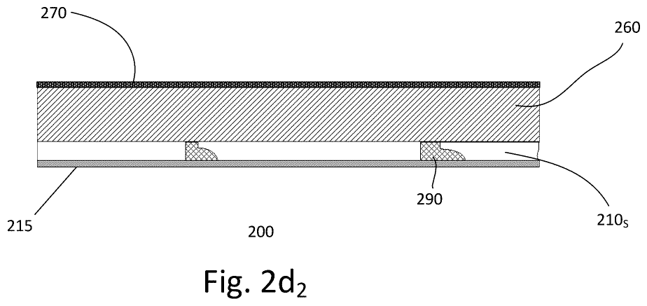

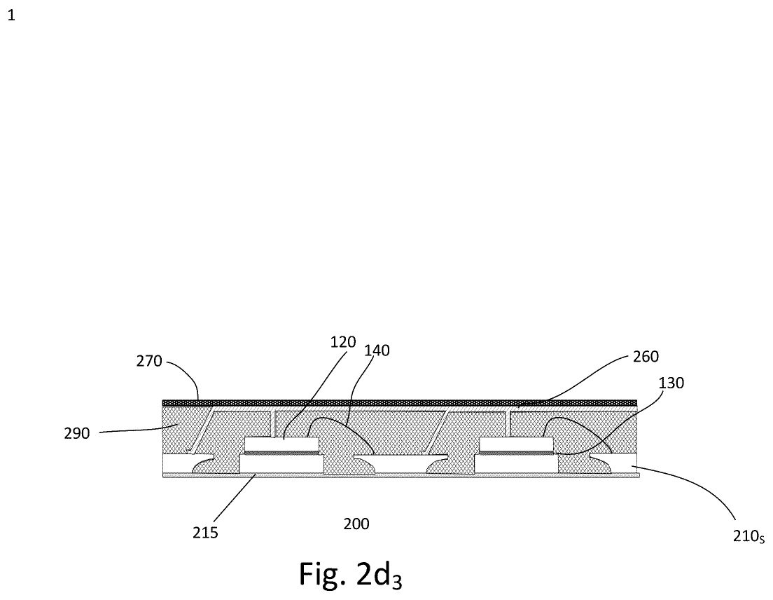

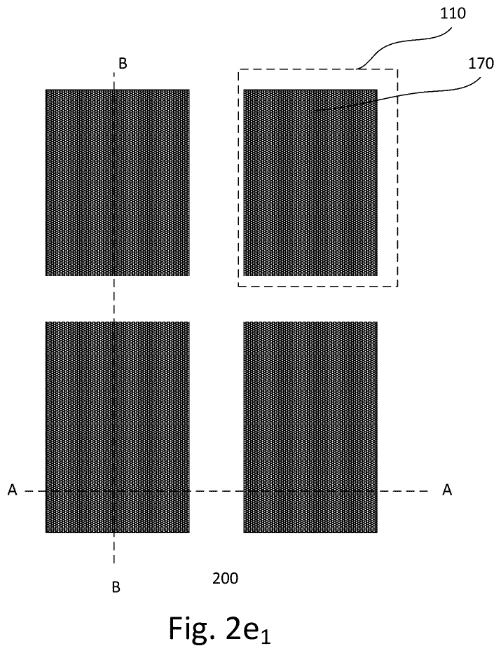

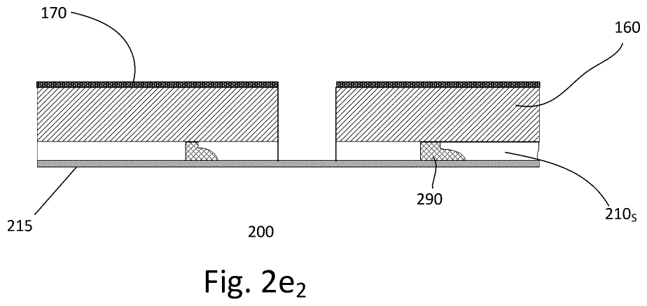

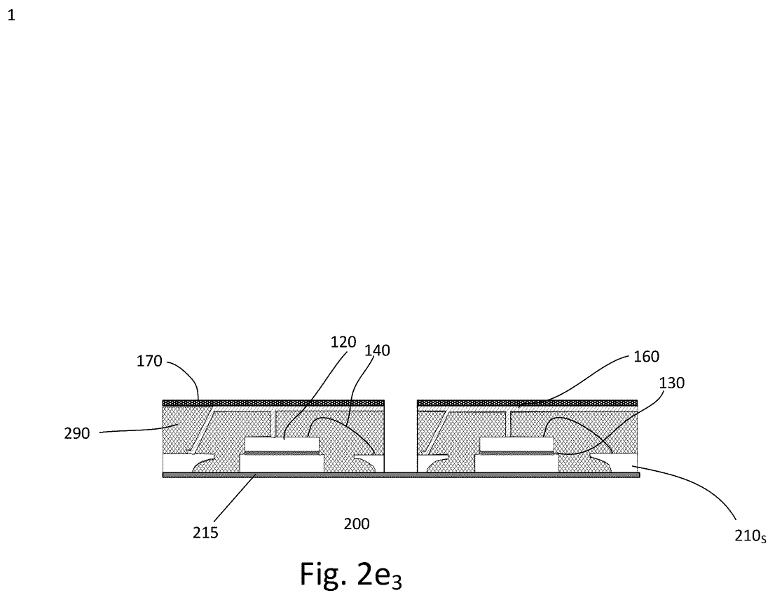

FIGS. 2a-2e show simplified views of an embodiment of a process 200 for forming packages in parallel. In particular, subscript 1 corresponds to top views of the process of forming packages in parallel whereas subscripts 2 and 3 correspond to cross-sectional views along A-A and B-B of the top view. When referring to FIGS. 2a-2e without subscripts, it is understood that the reference is made to all subscripted drawings. The packages include similar components as those described in FIGS. 1a-1g. Common elements may not be described or described in detail.

As shown in FIGS. 2a₁-2a₃, a package substrate strip 210s is attached to a carrier 215. The carrier, for example, may be a carrier tape to facilitate the processing of the package substrate strip. The package substrate strip includes a plurality of un-singulated package substrates 110. Each package substrate is used to form packages 100 in parallel. For example, a die package substrate includes package pads 114 and a DAP 112 for accommodating a die. The package pads may be disposed on a first side of the DAP. The package substrate includes a ground pad 114G disposed on an opposing second side of the DAP. This ground pad 114G, for example, is used to ground the primary heat dissipator. Other configurations of package pads may also be useful.

Illustratively, a package substrate is configured with three package pads on one side of the DAP. The package substrate may be configured for a power IC, such as a power metal oxide semiconductor field effect transistor (MOSFET). For example, a power IC generally has three terminals, power, ground and control terminals. The terminals of the die (die bond pads) on the active die surface 1211 are connected to the package pads by wire bonds 140. The die may be connected to the ground pad 114G.

As shown, the stage of processing includes dies 120 attached to the DAPs 112 of the substrate packages 110 of the substrate package strip 210s by adhesive 130. Wire bonds 140 connect die bond pads on the active surfaces 1211 of the dies to package pads on the package substrates. The dies on the package substrate sheet with wire bonds may be referred to as a package substrate strip assembly. It is understood package substrate strip assembly can refer to the package substrate strip with the dies at any stage of processing.

In FIGS. 2b₁-2b₃, a primary heat dissipator sheet 260 pre-formed with a plurality of un-singulated primary heat dissipators, is provided. The primary heat dissipator sheet, for example, may be made of a heat conductive sheet, such as a copper or copper alloy sheet. Other types of heat conductive sheets may also be useful. Pre-forming the primary heat dissipators may be achieved by stamping the sheet. Other techniques of pre-forming the plurality of heat dissipators may also be useful. The configuration of the plurality of primary heat dissipators on the primary heat dissipator sheet should preferably match that of the plurality of package substrates of the substrate strip.

The primary heat dissipator sheet is attached to the package substrate strip assembly. For example, the leg members of the package substrate sheet are connected to the ground terminals of the package substrates and the die connector members are connected to the active die surfaces of the dies. As discussed, the planar members should be sufficiently elevated above the wire bonds to prevent contact between them. Attaching the heat dissipator sheet to the package substrate sheet with dies may be achieved using thermally and electrically conductive adhesives. A curing process may be performed to cure the adhesive. Curing, for example, may be achieved by heat or UV curing.

Referring to FIGS. 2c₁-2c₃, a molding process is performed to encapsulate the package substrate strip assembly. For example, an encapsulant, such as an epoxy molding compound, encapsulates the packages on the package substrate strip by a transfer molding process. Other types of molding processes may also be useful.

As shown, the encapsulant is coplanar with the top surface of the primary dissipator sheet. For example, the top surface of the primary heat dissipator sheet is exposed by the encapsulant. In the case that the molding process is an injection or transferring molding, the mold compound covers the top of the planar member. Back grinding is performed to expose the planar member of the primary heat dissipator. Alternatively, the mold compound is deposited to be coplanar with the planar member, exposing the planar member surface, such as in the case of a film-assisted molding process. Other molding processes may be employed to form the encapsulant.

A secondary heat dissipator layer 270 is formed over the molded package substrate strip assembly, as shown in FIGS. 2d1-2d2. The secondary heat dissipator layer contacts the top surface of the planar member of the primary heat structure. For example, the primary heat dissipator sheet and the secondary heat dissipator layer are thermally connected to each other. In one embodiment, the secondary heat dissipator layer covers the entire top surface of the molded package substrate assembly.

In one embodiment, the secondary heat dissipator is a metallic layer, such as copper or a copper alloy. Other types of thermally conductive layers may also be useful. In one embodiment, the metallic layer is formed on the molded package substrate assembly by sputtering. Other techniques for forming the secondary heat dissipator layer on the molded package substrate assembly may also be useful. For example, the secondary heat dissipator layer may be formed by plating, such as electro or electroless plating. The sputtered or plated secondary heat dissipator layer may be about 1-3 μm. For example, the secondary heat dissipator may be a thin secondary heat dissipator layer. Other thicknesses may also be useful.

In other embodiments, the secondary heat dissipator layer includes a thick secondary heat dissipator layer. The thick secondary heat dissipator layer, for example, may be at least about 20 μm. Other thicknesses may also be useful. In one embodiment, the thick secondary heat dissipator layer may be a copper or copper-alloy metallic layer. Other types of thick thermally conductive metallic layers may also be useful. The thick metallic layer may be formed by a spray coating process or an attachment process. For example, an adhesive, such as dispensed or printed glue or printed paste may be employed.

After forming the secondary heat dissipator layer, as shown, in FIGS. 2e₁-2e₃, the molded package assembly strip with the secondary heat dissipator layer is singulated into individual packages 100. For example, the package strip is sawed in the x and y directions to singulate the package strip into individual packages. Other singulation processes may also be employed. In one embodiment, the process terminates after singulation. For example, the process ends after forming the singulated or individual packages.

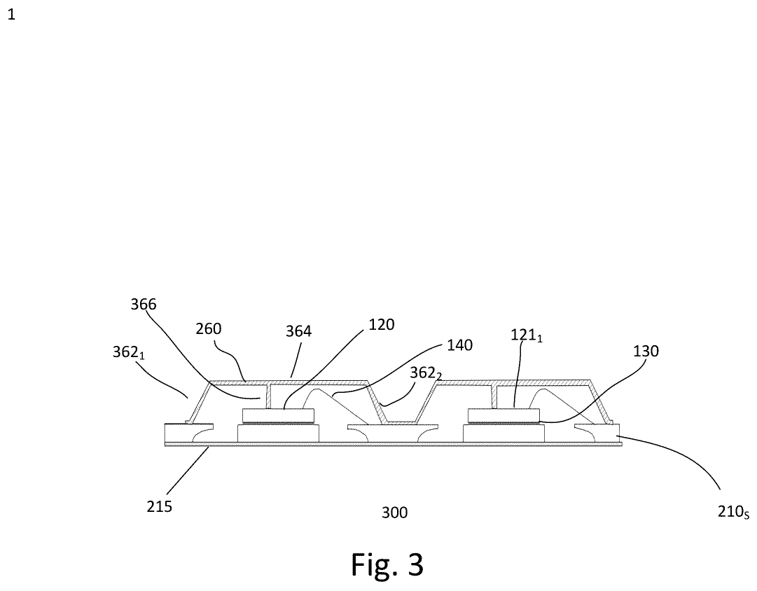

FIG. 3 shows an alternative process 300 of forming packages in parallel. The process is similar to that of FIGS. 2a-2e. Common elements may not be discussed or discussed in detail.

As shown, a primary heat dissipator sheet 260 is attached to the package substrate assembly, similar to what is described in FIGS. 2b₁-2b₃. For example, the primary heat dissipator sheet is attached to the package substrate strip 210s with dies 120 attached to the DAPs of the package substrates. As shown, the primary heat dissipator sheet is pre-formed with primary heat dissipators. Wire bonds 140 connect the package pads to the die pads on the active die surfaces 1211 of the dies. A primary heat dissipator includes first and second leg members 3621-2 extending downward from first and second opposing ends of the planar member 364. The primary heat dissipator also includes a die connector member 364 extending from the planar member to connect to the active die surface 121₁. The process continues as described in FIGS. 2c-2e to form individual packages.

In some embodiment, after forming the secondary heat dissipator layer 270, as shown in FIGS. 2d₁-2d₃, a tertiary heat dissipator layer may be formed over the secondary heat dissipator layer, as described in FIGS. 1d-1e. For example, the tertiary heat dissipator layer may be a thick dissipator layer or a heat sink layer. After forming the tertiary heat dissipator layer, the molded package substrate strip assembly is singulated into individual packages with primary, secondary and tertiary heat dissipators.

In other embodiments, the process of FIGS. 2a-2e may be modified to form flip-chip packages, as shown in FIGS. 1f-1g. In yet other embodiments, the process of FIGS. 2a-2e may be modified to form stacked die packages, as shown in FIG. 1h.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A method for forming a semiconductor package comprising:
providing a package substrate, the package substrate having top and bottom package substrate surfaces, wherein the top surface is configured with a die attach pad (DAP) and package pads;
attaching a bottom die surface of a die to the DAP, wherein the die is electrically coupled to the package pads;
attaching a primary heat dissipator to the package substrate and a top die surface of the die, wherein the primary heat dissipator comprises a planar member disposed over the top die surface, the heat dissipator is configured to dissipate heat from the die;
encapsulating the package substrate with an encapsulant, the encapsulant covers the package substrate and encases the die and the primary heat dissipator, wherein a top encapsulant surface is coplanar with the top planar member surface; and
forming a secondary heat dissipator on the top encapsulant surface, wherein the secondary heat dissipator contacts a top planar member surface of the primary heat dissipator to enhance heat dissipation from the die.

2. The method of claim 1 wherein attaching the primary heat dissipator to the package substrate includes electrically connecting the primary heat dissipator to ground.

3. The method of claim 1 wherein the primary heat dissipator comprises a pre-formed thermally conductive metallic structure.

4. The method of claim 1 wherein attaching the primary heat dissipator comprises a thermal adhesive for attaching the primary heat dissipator to the package substrate and die.

5. The method of claim 1 wherein the primary heat dissipator comprises a planar member with a leg member extending from a first side of the planar member to the package substrate and a die connector member extending from the planar member to contact the top die surface.

6. The method of claim 5 wherein:
the die comprises die pads on the top die surface;
wire bonds connect the die pads to package pads; and
wherein the planar member of the primary heat dissipator is disposed above the wire bonds to prevent the primary heat dissipator from interfering with the wire bonds.

7. The method of claim 1 wherein the primary heat dissipator comprises a planar member with first and second leg members extending from first and second sides of the planar member to the package substrate and a die connector member extending from the planar member to contact.

8. The method of claim 7 wherein:
the die comprises die pads on the top die surface;
wire bonds connect the die pads to package pads; and
wherein the planar member of the primary heat dissipator is disposed above the wire bonds to prevent the primary heat dissipator from interfering with the wire bonds.

9. The method of claim 1 wherein forming the secondary heat dissipator comprises sputtering a metallic layer on the top encapsulant surface.

10. The method of claim 1 further comprises forming a tertiary heat dissipator on a top surface of the secondary heat dissipator, wherein the tertiary heat dissipator further enhances heat dissipation of the die.

11. The method of claim 10 wherein forming the tertiary heat dissipator comprises sputtering a metallic layer on the secondary heat dissipator.

12. The method of claim 10 wherein forming the tertiary heat dissipator comprises attaching a heat sink to the secondary heat dissipator.

13. The method of claim 1 wherein the die comprises a flip-chip die, wherein
die contacts are disposed on the bottom die surface, the die contacts are coupled to package pads; and
the planar member of the primary heat dissipator directly contacts the top die surface.

14. The method of claim 1 wherein the die comprises a flip-chip die, wherein
die contacts are disposed on the bottom die surface, the die contacts are coupled to package pads;
a heat slug is disposed on the top die surface; and
the planar member of the primary heat dissipator directly contacts the heat slug surface.

15. A semiconductor package comprising:
a package substrate, the package substrate having top and bottom package substrate surfaces, wherein the top surface is configured with a die attach pad (DAP) and package pads;
a die having top bottom die surfaces, wherein the bottom die surface is disposed on the DAP, wherein the die is electrically coupled to the package pads;
a primary heat dissipator attached to the package substrate and a top die surface of the die, wherein the primary heat dissipator comprises a planar member disposed over the top die surface, the heat dissipator is configured to dissipate heat from the die;
an encapsulant, the encapsulant covers the package substrate and encases the die and the primary heat dissipator, wherein a top encapsulant surface is coplanar with a top planar member surface; and
a secondary heat dissipator disposed on the top encapsulant surface, wherein the secondary heat dissipator contacts the top planar member surface of the primary heat dissipator to enhance heat dissipation from the die.
